(19) United States
(12) Patent Application Publication
(10) Pub. No.: US 2012/0070913 A1
(43) Pub. Date: Mar. 22, 2012

(54) METHOD OF MANUFACTURING A SEMICONDUCTOR DEVICE AND SUBSTRATE PROCESSING APPARATUS

(75) Inventor: Tadashi HORIE, Toyama-shi (JP)

(73) Assignee: HITACHI KOKUSAI ELECTRIC INC., Tokyo (JP)

(21) Appl. No.: 13/238,228

(22) Filed: Sep. 21, 2011

(30) Foreign Application Priority Data
Sep. 22, 2010 (JP) 2010-212409

(51) Int. Cl. H01L 21/30; B05C 11/00

(52) U.S. Cl. 438/4; 118/696; 257/E21.211

(57) ABSTRACT

A method of manufacturing a semiconductor device includes: carrying a substrate having an oxide film and a nitride film stacked thereon into a processing chamber; supporting and heating the substrate using a substrate support member provided in the processing chamber; adjusting flow rates of hydrogen-containing gas and nitrogen-containing gas in process gas using a gas flow rate controller to set a percentage R of the number of hydrogen atoms with respect to the total number of hydrogen atoms and nitrogen atoms contained in the process gas to be 0%<R≦80%; supplying the process gas with the adjusted flow rates into the processing chamber using a gas supplying unit; exciting the process gas supplied into the processing chamber using a plasma generator; processing the substrate with the excited process gas; and carrying the substrate out of the processing chamber.

### CROSS-REFERENCE TO RELATED APPLICATION

This application is based upon and claims the benefit of priority from Japanese Patent Application No. 2010-212409, filed on Sep. 22, 2010, the entire contents of which are incorporated herein by reference.

### TECHNICAL FIELD

The present disclosure relates to a method of manufacturing a semiconductor device, which includes a process of nitrifying a thin film formed on a substrate, and a substrate processing apparatus which is used to perform such a process.

### BACKGROUND

A method of manufacturing a semiconductor device such as a flash memory may include a process of nitrifying an oxide film formed on a substrate. Such nitrification process is carried out by using a substrate processing apparatus including, for example, a processing chamber configured to process a substrate, a gas supplying unit configured to supply a process gas such as nitrogen gas into the processing chamber, a plasma generator configured to excite the supplied process gas, etc. The nitrification process includes carrying a substrate with an oxide film formed thereon into the processing chamber, exciting the process gas supplied into the processing chamber to a plasma state, and processing the substrate with the excited process gas.

As described above, in the related art, only nitrogen (N₂) gas has been used as a process gas for nitrification. However, the mere use of nitrogen gas provides an insufficient nitrification speed, which may result in difficulty in nitrifying an oxide film at a high density in a short time. In addition, as integrated circuits are miniaturized and device characteristics are improved, there is more of a need to increase a nitrification concentration when nitrifying an oxide film. However, the mere use of nitrogen gas makes it difficult to obtain a sufficient nitrification concentration.

### SUMMARY

The present disclosure provides some embodiments of a method of manufacturing a semiconductor device and a substrate processing apparatus, which are capable of increasing a nitrification speed and concentration of an oxide film.

According to one embodiment of the present disclosure, there is provided a method of manufacturing a semiconductor device, including: carrying a substrate having an oxide film and a nitride film stacked thereon into a processing chamber; supporting and heating the substrate using a substrate support member provided in the processing chamber; adjusting flow rates of hydrogen-containing gas and nitrogen-containing gas in process gas using a gas flow rate controller to set a percentage R of the number of hydrogen atoms with respect to the total number of hydrogen atoms and nitrogen atoms contained in the process gas to be 0%<R≦80%; supplying the process gas with the adjusted flow rates into the processing chamber using a gas supplying unit; exciting the process gas supplied into the processing chamber using a plasma generator; processing the substrate with the excited process gas; and carrying the substrate out of the processing chamber.

According to another embodiment of the present disclosure, there is provided a substrate processing apparatus including: a processing chamber into which a substrate having an oxide film and a nitride film stacked thereon is carried; a substrate support member provided in the processing chamber to support and heat the substrate; a gas flow rate controller configured to adjust flow rates of hydrogen-containing gas and nitrogen-containing gas in a process gas; a gas supplying unit which supplies the process gas into the processing chamber; a plasma generator configured to excite the process gas; and a control unit configured to control the substrate support member, the gas flow rate controller, the gas supplying unit and the plasma generator, wherein the control unit performs a control operation to heat the substrate carried into the processing chamber, adjust the flow rates of hydrogen-containing gas and nitrogen-containing gas such that a percentage R of the number of hydrogen atoms with respect to the total number of hydrogen atoms and nitrogen atoms in the process gas is set to be 0%<R≦80%, supply the process gas with the adjusted flow rates into the processing chamber, excite the process gas supplied into the processing chamber, and process the substrate with the excited process gas.

### BRIEF DESCRIPTION OF THE DRAWINGS

FIG. 1 is a sectional view of a modified magnetron-typed plasma processing apparatus as a substrate processing apparatus according to one embodiment of the present disclosure.

FIG. 2 is a flow chart showing a substrate processing method according to one embodiment of the present disclosure.

FIGS. 3A to 3D are schematic views showing how to form a gate structure on a substrate processed in the substrate processing method according to one embodiment of the present disclosure.

FIG. 4 is a graph showing a comparison between signal intensities of nitrogen in an oxide film obtained by fluorescent X-ray analysis according to Example 1 of the present disclosure and a comparative prior art example.

FIG. 5 is a graph showing a comparison between signal intensities of nitrogen in an oxide film obtained by fluorescent X-ray analysis according to Example 1 of the present disclosure and a comparative prior art example when processing time is changed.

FIG. 6 is a graph showing a tendency of change in signal intensities of nitrogen in an oxide film obtained by fluorescent X-ray analysis according to Example 2 of the present disclosure when a flow rate of nitrogen in process gas is changed.

FIG. 7 is a graph showing a tendency of change in signal intensities of nitrogen in an oxide film obtained by fluorescent X-ray analysis according to Example 3 of the present disclosure when the total amount of gas flow is changed.

FIG. 8 is a graph showing a tendency of change in signal intensities of nitrogen in an oxide film obtained by fluorescent X-ray analysis according to Example 4 of the present disclosure when an internal pressure of a processing chamber is changed during a discharge operation.

### DETAILED DESCRIPTION

### <Inventor's Findings>

Prior to description of embodiments of the present disclosure, findings by the inventor will be first described.

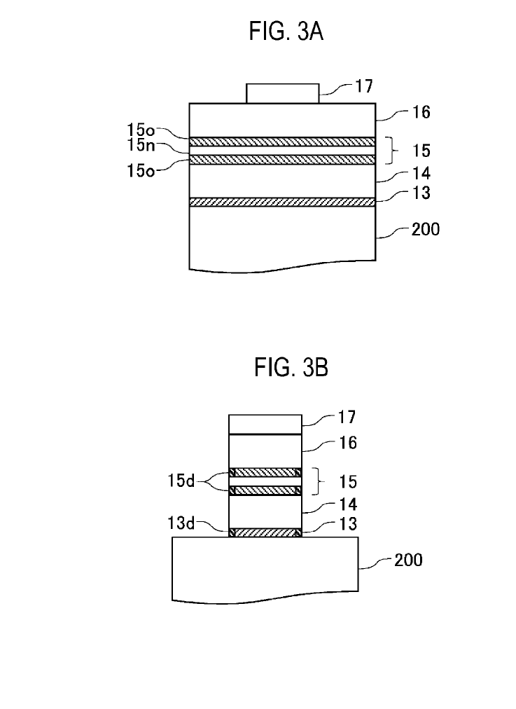

The above-mentioned nitrification process is performed for a gate oxide film of a flash memory or the like, for example, as shown in FIGS. 3A to 3D. The flash memory is formed by stacking, for example, a silicon oxide (SiO₂) film 13, a polysilicon (Poly-Si) film 14, an ONO film 15 [silicon oxide film 15o—silicon nitride (Si₃N₄) film 15n—silicon oxide 15o], and a polysilicon film 16 in this order on a wafer 200, such as a silicon substrate or the like (FIG. 3A), and patterning each of the films through dry etching or the like using a predetermined resist pattern 17 as a mask (FIG. 3B). The films act as a tunnel gate insulating film, a floating gate, an inter-electrode insulating film and a control gate, respectively.

When the stacked films are patterned, in some cases, the side walls of the silicon oxide films 13, 15o and 15o may be damaged in areas 13d and 15d. An oxidation process is performed to repair damaged areas 13d and 15d. However, bird's beaks 13b and 15b may be formed (see FIG. 3C). An oxidizing species used for the oxidation process may penetrate into the stacked films from their end portions and cause a reaction near an interface of the silicon oxide films 13, 15o and 15o, thereby oxidizing polysilicon films 14 and 16, and vertically contacting the silicon oxide films 13, 15o and 15o to form the bird's beaks 13b and 15b. Such bird's beaks 13b and 15b may reduce the capacitance of a gate structure and hence lower reliability of the semiconductor device.

However, if the silicon oxide films 13, 15o and 15o vertically contacting the polysilicon films 14 and 16 are nitrified in advance, oxidation is unlikely to extend toward the polysilicon films 14 and 16 in the oxidation process, thereby preventing the bird's beaks 13b and 15b from being formed (FIG. 3D).

As described above, the conventional nitrification process using, for example, N₂ gas solely can hardly nitrify the silicon oxide films 13, 15o and 15o and the like with a high concentration in a short time. This requires a long nitrification process time, which might lead to low productivity. The present inventor has tried methods of increasing temperature for nitrification process, increasing high frequency power in generating plasma, etc. in order to increase a nitrification speed. However, in many cases, the trial methods caused harmful effects such as the production and adhesion of particles to the wafer 200, metal contamination and so on.

Thus, the present inventor has conducted more elaborate studies on methods of increasing the nitrification speed without relying on the earlier methods. As a result, the present inventor has found that a nitrification process under the existence of hydrogen-containing gas can increase the nitrification speed. The present disclosure is based on the present inventor's findings.

### <One Embodiment of the Present Disclosure>

### (1) Configuration of Substrate Processing Apparatus

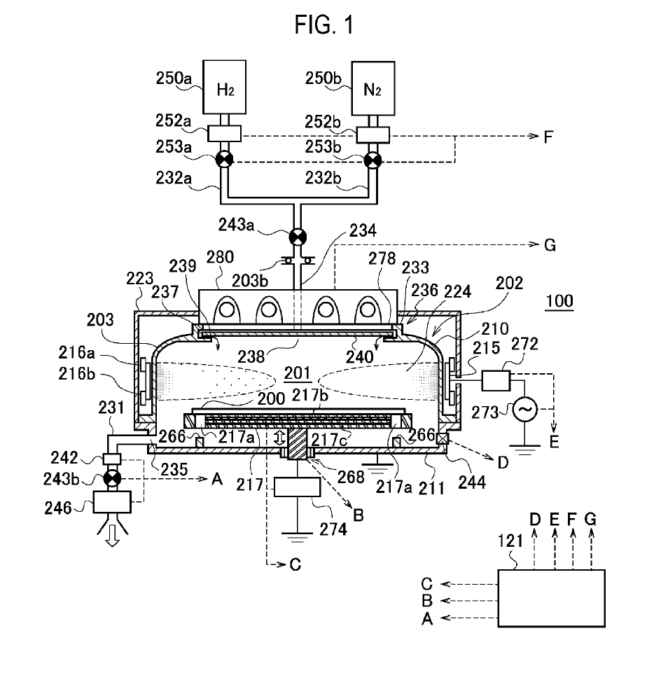

A substrate processing apparatus according to one embodiment of the present disclosure will now be described in detail with reference to the drawings. FIG. 1 is a sectional view of a modified magnetron-type plasma processing apparatus as a substrate processing apparatus according to one embodiment of the present disclosure.

The substrate processing apparatus according to this embodiment is a modified magnetron-type plasma processing apparatus 100 (hereinafter referred to as an “MMT apparatus”) which provides plasma processing for a wafer 200, such as a silicon substrate, using a modified magnetron-type plasma source which is able to generate high density plasma using an electric field and a magnetic field. The MMT apparatus 100 is configured to produce magnetron discharge by applying a high frequency voltage, under a constant pressure, to process gas introduced into an airtight processing chamber 201 having a wafer 200 loaded therein. Through such a mechanism, the MMT apparatus 100 excites the process gas to perform various kinds of plasma processing, for example, a diffusion processing, such as oxidation, nitrification and so on, for the wafer 200, a thin film formation processing, an etch processing etching a surface of the wafer 200, and the like.

### (Processing Chamber)

The MMT apparatus 100 includes a processing furnace 202 for processing the wafer 200 with plasma. The processing furnace 202 is provided with a processing container 203 constituting the processing chamber 201. The processing container 203 includes a first upper dome-like container 210 and a second lower bowl-like container 211. The processing chamber 201 is formed by placing the upper container 210 on the lower container 211. The upper container 210 is made of, for example, nonmetallic material such as aluminum oxide (Al₂O₃) or quartz (SiO₂) and the lower container 211 is made of, for example, aluminum (Al).

In addition, a gate valve 244 is provided in a lower side wall of the lower container 211. In its opened state, the gate valve 244 is configured to carry the wafer 200 into or out of the processing chamber 201 by means of a carrying mechanism (not shown). In its closed state, the gate valve 244 is configured to serve as a sluice valve to keep the processing chamber 201 airtight.

### (Susceptor)

A susceptor 217 configured to support the wafer 200 is placed in the center of the bottom of the processing chamber 201. The susceptor 217 is made of, for example, nonmetallic material such as aluminum nitride (AlN), ceramics, quartz or the like and is configured to reduce metallic contamination such as contaminant films formed on the wafer 200.

A heater 217b as a heating mechanism is integrally embedded in the susceptor 217. When the heater 217b is powered, it is configured to heat the surface of the wafer 200 to, for example, about 25° C. to 500° C.

The susceptor 217 is electrically isolated from the lower container 211. An impedance tuning electrode 217c is equipped within the susceptor 217 and is grounded via an impedance varying mechanism 274 as an impedance tuner. The impedance tuning electrode 217c acts as a second electrode with respect to a barrel-like electrode 215 as a first electrode which will be described later. The impedance varying mechanism 274 may include a coil and a variable capacitor and is configured to control an electric potential (or bias voltage) of the wafer 200 through the impedance tuning electrode 217c and the susceptor 217 by controlling the number of windings of the coil and capacitance of the variable capacitor.

The susceptor 217 is provided with a susceptor elevating mechanism 268. The susceptor 217 is formed with at least three through holes 217a. In the bottom of the lower container 211 are provided at least three corresponding substrate push-up pins 266. When the susceptor 217 is lowered by the susceptor elevating mechanism 268, the substrate push-up pins 266 are inserted in the through holes 217a with the substrate push-up pins 266 in no contact with the susceptor 217. In addition, the susceptor elevating mechanism 268 has a susceptor rotation function to rotate the susceptor 217 around a vertical axis passing the center of the top of the susceptor 217. The susceptor 217 is configured to improve uniformity of plasma processing on the surface of the wafer 200 by rotating the wafer 200 during plasma processing.

According to this embodiment, the substrate supporting unit includes a susceptor 217 and a heater 217b.

### (Lamp Heater Unit)

A light transmission window 278 is provided in the upper part of the processing chamber 201, that is, on the top of the upper container 210, and a lamp heater unit 280 is provided on the light transmission window 278 outside the processing container 203. The lamp heater unit 280 is configured to adjust the surface temperature of the wafer 200 to 500° C. to 900° C. in cooperation with the heater 217b.

### (Gas Supplying Unit)

A shower head 236 is provided in the upper part of the processing chamber 201, that is, on the top of the upper container 210. The shower head 236 includes a cap-shaped cover 233, a gas inlet hole 234, a buffer chamber 237, an opening 238, a shield plate 240 and a gas outlet hole 239 and is configured to supply a process gas into the processing chamber 201. The buffer chamber 237 serves as a distribution space to distribute the process gas introduced through the gas inlet hole 234.

The gas inlet hole 234 is connected to a junction of the downstream end of a hydrogen-containing gas supplying pipe 232a for supplying hydrogen (H₂) gas as hydrogen-containing gas and the downstream end of a nitrogen-containing gas supplying pipe 232b for supplying nitrogen (N₂) gas as nitrogen-containing gas. The hydrogen-containing gas supplying pipe 232a is provided with a H₂ gas source 250a, a mass flow controller 252a, a valve 253a as an opening/closing valve, which are sequentially arranged. The nitrogen-containing gas supplying pipe 232b is provided with a N₂ gas source 250b, a mass flow controller 252b, a valve 253b as an opening/closing valve, which are sequentially arranged. A valve 243a is provided downstream of the junction at which the hydrogen-containing gas supplying pipe 232a and the nitrogen-containing gas supplying pipe 232b join together, and is connected to the upstream end of the gas inlet hole 234 via a gasket 203b. By opening/closing the valves 253a, 253b and 243a, it is configured so that the process gas including the hydrogen-containing gas and the nitrogen-containing gas can be supplied into the processing chamber 201 via the gas supplying pipes 232a and 232b while regulating respective flow rates of gas by means of the mass flow controllers 252a and 252b.

A gas flow rate controller according to this embodiment includes mass flow controllers 252a and 252b. In addition, the gas supplying unit includes the shower head 236 (including the cap-shaped cover 233, the gas inlet hole 234, the buffer chamber 237, the opening 238, the shield plate 240 and the gas outlet hole 239), the hydrogen-containing gas supplying pipe 232a, the nitrogen-containing gas supplying pipe 232b, the H₂ gas source 250a, the N₂ gas source 250b, the mass flow controllers 252a and 252b, and valves 253a, 253b and 243a.

### (Exhausting Unit)

A gas exhaustion hole 235 for exhausting the process gas from the processing chamber 201 is provided in the side wall of the lower container 211. The gas exhaustion hole 235 is connected to the upstream end of a gas exhausting pipe 231. The gas exhausting pipe 231 is provided with an auto pressure controller (APC) 242 as a pressure regulator (pressure regulating unit), a valve 243b as an opening/closing valve, and a vacuum pump 246 as a vacuum exhaustion device, which are sequentially arranged.

An exhausting unit according to this embodiment includes the gas exhaustion hole 235, the gas exhaustion pipe 231, the APC 242, the valve 243b and the vacuum pump 246.

### (Plasma Generating Unit)

A barrel-like electrode 215 as a first electrode is provided in the outer circumference of the processing chamber 201, that is, the outer wall of the upper container 210, to surround the processing chamber 201. The barrel-like electrode 215 has a barrel shape, for example, a cylindrical shape. The barrel-like electrode 215 is connected to a high frequency power supply 273 for applying high frequency power via a matching device 272 for impedance matching.

An upper magnet 216a and a lower magnet 216b are provided at an upper end and a lower end of an outer surface of the barrel-like electrode 215, respectively. The upper magnet 216a and the lower magnet 216b both include a barrel-like (e.g., cylindrical) permanent magnet. The upper magnet 216a and the lower magnet 216b have magnetic poles in their surfaces facing the processing chamber 201 and their opposite surfaces. The magnetic poles of the upper magnet 216a are arranged in a reverse order with respect to those of the lower magnet 216b. That is, the magnetic poles of the upper magnet 216a facing the processing chamber 201 are different from those of the lower magnet 216b facing the processing chamber 201. This produces a line of magnetic force in a cylindrical axial direction along the inner surface of the barrel-like electrode 215.

By generating a magnetic field by means of the upper magnet 216a and the lower magnet 216b and generating an electric field with high frequency power applied to the barrel-like electrode 215 after introducing the process gas into the processing chamber 201, magnetron discharging plasma is generated in a plasma generation region 224 within the processing chamber 201. As the above-mentioned electromagnetic field rotates released electrons, it is possible to increase the ionization rate of plasma to provide high density plasma having a long lifetime.

In addition, a metallic shield plate 223 for effectively shielding the electromagnetic field is provided around the upper magnet 216a and the lower magnet 216 to prevent the electromagnetic field from having an adverse effect on other devices or external environments.

A plasma generating unit includes the barrel-like electrode 215, the matching device 272, the high frequency power supply 273, the upper magnet 216a and the lower magnet 216.

### (Control Unit)

A controller 121 as a control unit is configured to control the APC 242, the valve 243b and the vacuum pump 246 through a signal line A, the susceptor elevating mechanism 268 through a signal line B, the heater 217b and the impedance varying mechanism 274 through a signal line C, the gate valve 244 through a signal line D, the matching device 272 and the high frequency power supply 273 through a signal line E, the mass flow controllers 252a and 252b and the valves 253a, 253b and 243a through a signal line F, and the lamp heater unit 280 through a signal line G

### (2) Substrate Processing Method

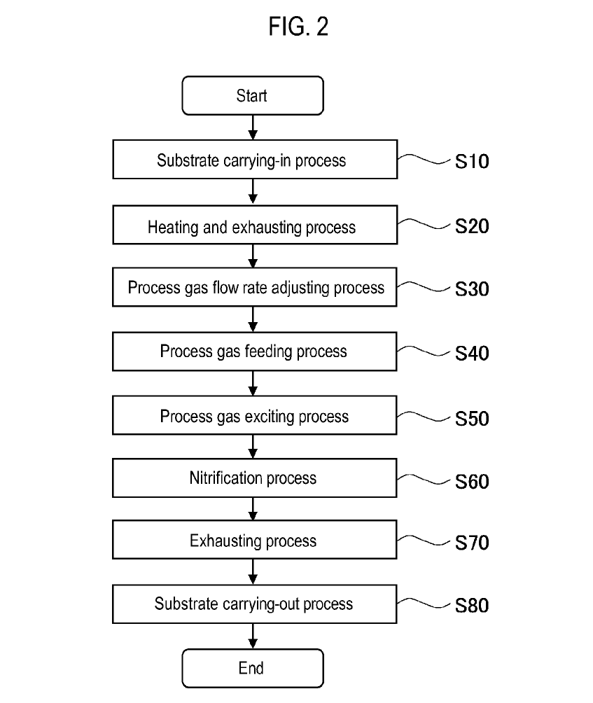

Next, a substrate processing method according to this embodiment will be described with reference to FIG. 2. FIG. 2 is a flow chart showing a substrate processing method according to one embodiment of the present disclosure. The substrate processing method according to this embodiment may be performed by the above-mentioned MMT apparatus 100, for manufacturing semiconductor devices such as flash memories. In the following description, operation of various parts of the MMT apparatus 100 is controlled by the controller 121.

In addition, for example, the silicon oxide films 15o and 15o or the silicon nitride film 15n shown in FIG. 3A are already formed on the wafer 200 to be processed in the substrate processing method according to this embodiment. Here, with the presumption that the films that extend up to the silicon oxide film 15o on the silicon nitride film 15n are formed in the stacked films shown in FIG. 3A, a nitrification process to mainly nitrify the silicon oxide film 15o on the silicon nitride film 15n before forming the polysilicon film 16 will be described.

### (Substrate Carrying-In Process S10)

First, the wafer 200 is carried into the processing chamber 201. Specifically, the susceptor 217 is moved down to a carrying position of the wafer 200 and the wafer push-up pins 266 are inserted in the through holes 217a of the susceptor 217. As a result, the push-up pins 266 project from the surface of the susceptor 217 by a predetermined height.

Subsequently, the gate valve 244 is opened and the wafer 200 is carried into the processing chamber 201 from a vacuum carrying chamber (not shown) adjacent to the processing chamber 201 by means of the carrying mechanism (not shown). As a result, the wafer 200 is horizontally supported on the wafer push-up pins 266 projecting from the surface of the susceptor 217. When the wafer 200 is carried into the processing chamber 201, the carrying mechanism is withdrawn from the processing chamber 201 and the gate valve 244 is closed to seal the processing chamber 201. Then, the susceptor elevating mechanism 268 is used to raise the susceptor 217. As a result, the wafer 200 is supported on the top of the susceptor 217. Thereafter, the wafer 200 is raised up to a predetermined processing position. In the meantime, the rotation function of the susceptor elevating mechanism 268 is used to start rotation of the wafer 200. As this rotation continues until exhausting process S70, which will be described later, is ended, it is possible to improve uniformity of substrate processing in the surface of the wafer 200. In addition, the substrate carrying-in process S10 may be performed while purging the processing chamber 201 by filling it with inert gas or the like.

### (Heating and Exhausting Process S20)

Subsequently, by applying power to the heater 217b embedded in the susceptor 217, the surface of the wafer 200 is heated to a predetermined temperature by the susceptor 217 pre-heated to a predetermined temperature (25° C. to 500° C.). In addition, if the wafer 200 is to be heated to 500° C. to 900° C., the lamp heater unit 280 of the apparatus is used. In addition, while the wafer 200 is being heated, the processing chamber 201 is exhausted through the gas exhausting pipe 231 by means of the vacuum pump 246 such that the internal pressure of the processing chamber 201 is within a range between 0.1 Pa and 100 Pa. The vacuum pump 246 is under activation until a substrate carrying-out process, which will be described later, is ended.

### (Process Gas Flow Rate Regulating Process S30)

Next, flow rates of the H₂ gas as the hydrogen-containing gas and the N₂ gas as the nitrogen-containing gas are regulated. Specifically, the valves 253a, 253b and 243a are opened. At first, the H₂ gas and the N₂ gas are introduced into the gas supplying pipes 231a and 232b, respectively. At this time, the flow rates of the H₂ gas and the N₂ gas in the gas supplying pipes 232a and 232b are regulated by the mass flow controller 252a and 252b as gas flow rate controllers, respectively. The H₂ gas and the N₂ gas with the regulated flow rates flow into the gas supplying pipes 232a and 232b and join and mix together downstream to provide the processing gas containing the H₂ gas and the N₂ gas.

At this time, the flow rates of the H₂ gas and the N₂ gas are regulated such that a percentage of the number of hydrogen atoms with respect to the total number of hydrogen and nitrogen atoms contained in the process gas is, for example, more than 0% and less than 80%. That is, assuming that the percentage R is defined by [the number of hydrogen atoms/(the number of hydrogen atoms+the number of nitrogen atoms)]×100(%), the flow rates are regulated to become 0%<R<80%, for example. In this embodiment, when the percentage of the flow rate of the H₂ gas with respect to the sum of flow rates of the H₂ gas and N₂ gas contained in the process gas is more than 0% and less than 80%, the percentage R of the hydrogen atoms is satisfied. This can increase a nitrification speed. More specifically in some embodiments, a higher increase is realized when the percentage of the number of hydrogen atoms is more than 5% and less than 75%. This can nitrify an oxide film with high concentration.

In addition, the flow rates of the H₂ gas and N₂ gas are set to be within a range between 100 sccm and 1000 sccm, for example. Specifically, the total flow rate of the process gas containing the H₂ gas and N₂ gas is set to be more than 200 sccm and less than 1000 sccm. This can increase supply efficiency of nitrogen activated species generated in a subsequent process and supplied to the wafer 200 to increase the nitrification speed. More specifically, the total flow rate of the process gas containing the H₂ gas and N₂ gas is set to be more than 600 sccm. This can nitrify an oxide film with high concentration while increasing supply efficiency of nitrogen activated species generated in a subsequent process and supplied to the wafer 200 to further increase the nitrification speed.

### (Process Gas Supplying Process S40)

When the valves 253a, 253b and 243a are opened in the process gas flow rate regulating process S40, the process gas containing the H₂ gas and N₂ gas with the regulated flow rates is supplied into the processing chamber 201. At this time in some embodiments, the degree the APC 242 is opened is adjusted so that the internal pressure of the processing chamber 201 is within a range of between 0.1 Pa and 100 Pa, and more specifically, a range between 8 Pa and 100 Pa. This can provide a pressure appropriate for formation of ions in plasma, which will be described later, to increase the nitrification speed and nitrify the silicon oxide film with high concentration. The degree the APC 242 is opened may be adjusted so that the internal pressure of the processing chamber 201 is within a range between 25 Pa and 80 Pa. This can achieve nitrification with higher concentration. The supply of the process gas continues until a nitrification process S60, which will be described later, ends.

### (Process Gas Exciting Process S50)

When the internal pressure of the processing chamber gets stable, the high frequency power supply 273 applies high frequency power to the barrel-like electrode 215 via the matching device. At this time, a frequency of the high frequency power is, for example, 13.56 MHz and the applied high frequency power has an output value between 150 W and 1000 W. This excites the process gas containing the H₂ gas and N₂ gas to a plasma state in the processing chamber 201, more specifically, in the plasma generation region 224 above the wafer 200. The H₂ gas and N₂ gas in the plasmarized process gas are decomposed into hydrogen activated species and nitrogen activated species, that is, hydrogen radicals (H*), nitrogen radicals (N*), hydrogen ions (H⁺), nitrogen ions (N⁺), other radicals and ions, etc.

In addition, the impedance varying mechanism 274 controls the susceptor 217 to have a predetermined impedance value in advance. This enables control of an electric potential of the susceptor 217, further an electric potential (bias voltage) of the wafer 200. At this time, when the impedance value is controlled to increase the bias voltage of the wafer 200, the amount of ions incident on the wafer 200 on the susceptor 217 can be increased to increase the nitrification speed. In addition, by adjusting the impedance value to obtain the bias voltage to allow a penetration depth of nitrogen into the wafer 200 to be a predetermined depth, a particular film in the stacked films, for example, the upper silicon oxide film 15o, can be nitrified.

In addition, the impedance varying mechanism 274 may adjust a phase difference of electric potential between the susceptor 217, which is varied in its electric potential, and plasma. When the absolute value of a potential difference between the susceptor 217 and the plasma is controlled to increase with phase inversion (by about 180°) of the susceptor 217 and the plasma, the supplying amount of the nitrogen activated species and hydrogen activated species onto the wafer 200 can be increased to increase the nitrification speed. Alternatively, when the phase difference is adjusted to be within a range of between 0° and 180° to take a balance between the nitrification speed and uniformity of the nitrogen concentration in the surface of the wafer 200, both the nitrification speed and the uniformity can be within an allowable range.

### (Nitrification Process S60)

After the process gas is excited by the high frequency power, a plasma processing is performed for the surface of the wafer 200 using the excited process gas. The nitrogen activated species in the plasma penetrate into and nitrify the silicon oxide film 15o. Then, the silicon oxide film 15o is modified into a silicon nitride (SiN) film or a silicon oxynitride (SiON) film. At this time, the nitrogen activated species and the hydrogen activated species are supplied onto the surface of the wafer 200 to reduce the silicon oxide film. When the silicon oxide film is reduced, it is considered that dangling bonds of Si are generated to make Si and nitrogen react with each other easily to increase the nitrification speed. In addition, nitrogen bonds Si directly with no intervention of impure atoms such as oxygen atoms and the like, to provide silicon nitride or silicon oxynitride having a bond level higher than that processed only by nitrogen activated species. In addition, oxygen generated by reduction and water (H₂O) generated by reaction with hydrogen activated species are separated from the silicon oxide and are exhausted along with an atmosphere.

After the nitrification process, annealing may be carried out in order to provide a strong bond between the silicon oxide film 15o and nitrogen. In this case, if the bond of nitrogen contained in the silicon oxide film 15o by the nitrification process is too weak, the nitrogen escapes from the silicon oxide film 15o due to high annealing temperature. However, in this embodiment, since the nitrogen in the silicon oxide film 15o is in a stable state, it is possible to prevent the nitrogen from escaping during the annealing.

Thereafter, when a predetermined period of processing time (for example, 9 to 15 seconds) elapses, the valve 253a is closed to stop the supply of H₂ gas into the processing chamber 201 and, approximately at the same time, the application of power from the high frequency power supply is stopped. Thereafter, the processing chamber 201, after plasma discharge, is mainly filled with an N₂ gas atmosphere. By first stopping the supply of the H₂ gas, the process remains unfinished while leaving the dangling bonds of Si generated by the reaction of the hydrogen activated species and the silicon oxide film. Leaving the dangling bonds of Si may change characteristics of the thin film due to reaction of the dangling bonds of Si with oxygen in a subsequent process. In addition, this may prevent reaction of the silicon oxide film, which is highly heated during the process, with the remaining H₂ gas. After stopping the supply of the H₂ gas, the nitrogen bonds with the dangling bonds of Si. This improves stability of the processed thin film.

Thereafter, the valves 253b and 243a are closed and the supply of the N₂ gas into the processing chamber 201 is stopped. Thus, the silicon oxide film 15o is nitrified (modified) and the nitrification process S60 ends.

### (Exhausting Process S70)

When the supply of the N₂ gas is stopped, the gas exhausting pipe 231 is used to exhaust the processing chamber 201. Accordingly, the N₂ gas, the H₂ gas and exhaustion gas generated by the reaction of the N₂ gas and H₂ gas are exhausted out of the processing chamber 201. Thereafter, the degree that the APC 242 is opened is adjusted to set the internal pressure of the processing chamber 201 to the same pressure (for example, 100 Pa) as the vacuum carrying chamber (a carrying-out destination of the wafer 200, not shown) adjacent to the processing chamber 201.

### (Substrate Carrying-Out Process S80)

When the processing chamber 201 is under a predetermined pressure, the susceptor 217 descends down to a carrying position of the wafer 200 to support the wafer 200 on the wafer push-up pins 266. Then, the gate valve 244 is opened and the carrying mechanism (not shown) is used to carry the wafer 200 out of the processing chamber 201. In this case, the substrate may be carried out while purging the processing chamber 201 with inert gas or the like. Thus, the substrate processing method according to this embodiment ends.

<Effects of This embodiment>

This embodiment shows one or more effects as follows:

(a) According to this embodiment, the process gas containing the H₂ gas and N₂ gas is used to perform the nitrification process and the percentage of the number of hydrogen atoms with respect to the total number of hydrogen and nitrogen atoms contained in the process gas is, for example, more than 0% and less than 80%. This can increase the nitrification speed of the silicon oxide film 15o to nitrify the film in a shorter time.

(b) According to this embodiment, the process gas containing the H₂ gas and N₂ gas is used to perform the nitrification process and the percentage of the number of hydrogen atoms with respect to the total number of hydrogen and nitrogen atoms contained in the process gas is, for example, more than 5% and less than 75%. This can increase the nitrification speed of the silicon oxide film 15o. This can also achieve the nitrification with still higher concentration to realize recent miniaturization of integrated circuits and nitrification concentration required for semiconductor devices.

(c) According to this embodiment, the above-configuration allows nitrogen penetrating into the silicon oxide film 15o to be in a stable bonding state. Accordingly, it is possible to prevent the nitrogen from escaping from the silicon oxide film 15o in subsequent annealing and hence keeps the nitrogen in the silicon oxide film 15o at a high concentration even after the annealing.

(d) According to this embodiment, the total flow rate of the processing gas is set to more than 600 sccm. In addition, the internal pressure of the processing chamber 201 is set to more than 25 Pa and less than 80 Pa. One or both of these conditions may be employed to increase the nitrification speed.

(e) According to this embodiment, the nitrification process by plasma is performed while adjusting the bias voltage of the wafer 20 by means of the impedance varying mechanism 274. This can achieve a particular nitrification speed and, particularly, the nitrification speed can be more increased when the bias voltage of the wafer 200 is increased.

(f) According to this embodiment, as the adjustment of the bias voltage allows a penetration depth of nitrogen into the wafer 200 to be a predetermined depth, a particular film in the stacked films shown in FIG. 3A to 3D, for example, the upper silicon oxide film 15o, can be nitrified. At this time, the nitrogen may penetrate to a depth of an underlying film of the stacked films to nitrify the lower silicon oxide film 15o simultaneously. This allows a batch process for the plurality of films, which may reduce the number of processes.

(g) According to this embodiment, the impedance varying mechanism 274 adjusts a phase difference of electric potential between the susceptor 274 and the plasma to be within a range between 0° and 180°. This can invert the phase by about 180° to increase the nitrification speed. In addition, when the phase difference is adjusted to be within the range between 0° and 180°, both the nitrification speed and the uniformity on the surface of the wafer 200 can be within an allowable range.

(h) According to this embodiment, at a timing when high frequency power to generate the plasma is stopped, the supply of the H₂ gas is stopped earlier than the supply of the N₂ gas. By first stopping the supply of the H₂ gas, the process remains unfinished while leaving the dangling bonds of Si generated by the reaction of the hydrogen activated species and the silicon oxide film. Leaving the dangling bonds of Si may change characteristics of the thin film due to reaction of the dangling bonds of Si with oxygen in a subsequent process. In addition, this may prevent reaction of the silicon oxide film highly heated during process with the remaining H₂ gas. This improves stability of the processed thin film.

(i) By applying this embodiment to stacked films of semiconductor devices such as flash memories as shown in FIG. 3A, the nitrification process can be performed with high concentration and high throughput, which may result in prevention of a bird's beak and hence high reliability of semiconductor devices.

### <Other Embodiments of the Present Disclosure>

Although particular embodiments have been illustrated above, the present disclosure is not limited thereto but may be modified in various ways without departing from the spirit and scope of the present disclosure.

For example, although it has been illustrated that the H₂ gas is used as the hydrogen-containing gas and the N₂ gas is used as the nitrogen-containing gas, other hydrogen-containing gas and nitrogen-containing gas may be used. For example, ammonia (NH₃) gas may be used as the hydrogen-containing gas. When the NH₃ gas is used to set the percentage R of hydrogen atoms in the process gas to be 75%, the NH₃ gas may be used solely with a flow rate of the nitrogen-containing gas adjusted to 0 sccm. In addition, the nitrogen-containing gas may be added to the NH₃ gas to set the percentage R of hydrogen atoms in the process gas to be less than 75%. Alternatively, hydrogen-containing gas other than the NH₃ gas may be further added to provide a particular percentage R.

In addition, although it has been illustrated in the disclosed embodiment that the percentage of hydrogen atoms is more than 0% and less than 80%, more specifically, more than 5% and less than 75%, an effect of increasing the nitrification speed is achieved under the existence of hydrogen-containing gas even if the hydrogen atoms are beyond such a range of percentage. Accordingly, it is possible to set the nitrogen concentration in the oxide film to a particular value by extending the time of the nitrification process.

In addition, although it has been illustrated in the disclosed embodiment that the supply of H₂ gas is stopped at about the same time as stopping the high frequency power, the supply of H₂ gas may be stopped after stopping the high frequency power or may be stopped at about the same time as stopping the supply of N₂ gas.

In addition, although it has been illustrated in the disclosed embodiment that the silicon oxide film 15o and the like are nitrified after the ONO film 15 is stacked, the nitrification process may be performed for each film or films stacked halfway, and thus, a timing for nitrification of each film may be selected randomly. Accordingly, a degree of freedom of a sequence of process can be increased.

In addition, although it has been illustrated in the disclosed embodiment that the nitrification process is performed after film formation, the nitrification process may be performed after patterning the stacked films. It is possible to nitrify the stacked films by penetrating nitrogen in the stacked films through a patterned end portion of each film.

In addition, although it has been illustrated in the disclosed embodiment that only the nitrification process is performed in the MMT apparatus 100, a nitride film and an oxide film may be formed in the MMT apparatus 100 and a nitrification process may be continuously performed in the same processing chamber 201.

In addition, although it has been illustrated in the disclosed embodiment that the present disclosure is applied to flash memories, the present disclosure may be applied to other semiconductor devices including gate insulating films of dynamic random access memories (DRAMs) and so on.

In addition, although it has been illustrated in the disclosed embodiment that the silicon oxide film 15o and so on are subjected to the nitrification process, oxide films to be nitrified may include high-k films such as hafnia (HfO₂), hafnium silicate (HfSiₓO_{y}), zirconia (ZrO₂), zirconium silicate (ZrSiₓO_{y}) and the like, or films containing Al, Ti, W and the like.

In addition, although it has been illustrated in the disclosed embodiment that the substrate processing method is performed by the MMT apparatus 100, available substrate processing apparatuses are not limited to the MMT apparatus 100 but may include, for example, an inductively coupled plasma (ICP) type plasma processing apparatus and an electron cyclotron resonance (ECR) type plasma processing apparatus.

### EXAMPLES

Next, Examples 1 to 4 of the present disclosure will be described. In the following Examples, a plurality of samples, each of which has a silicon oxide film formed with a thickness of 10 nm on a silicon substrate, was prepared and nitrified under different conditions and the amount and state of nitrogen in the silicon oxide film were examined. The nitrification process was performed using the MMT apparatus 100 of the disclosed embodiment shown in FIG. 1 and on the basis of the substrate processing method shown in FIG. 2.

### Example 1

Example 1 of the present disclosure will be now described in conjunction with a comparative prior art example. In Example 1, H₂ gas and N₂ gas were used to perform a nitrification process for the samples and the amount and state of nitrogen in the silicon oxide film were compared with those of samples in the comparative example which used only N₂ gas for the nitrification process.

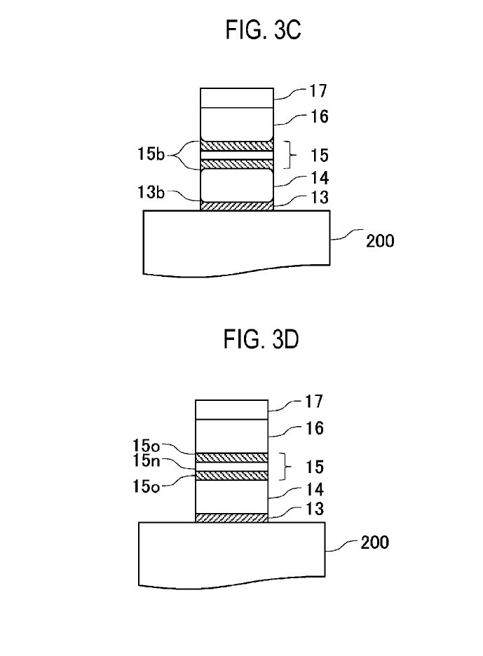

FIG. 4 shows data compared in terms of signal intensities of nitrogen in a silicon oxide film of samples obtained by fluorescent X-ray analysis according to Example 1 and a comparative prior art example. The left side of FIG. 4 shows data representing Example 1 and the right side thereof shows data representing the comparative example. In FIG. 4, a vertical axis represents relative signal intensity (a. u.) of nitrogen in the silicon oxide film according to fluorescent X-ray analysis. This signal intensity has a correlation with nitrogen concentration in the silicon oxide film, i.e., the higher signal intensity provides the higher nitrogen concentration. Detailed conditions for (a) Example 1 (using H₂ gas and N₂ gas) and (b) comparative example (using only N₂ gas) are as follows:
(a) Conditions for Example 1
   High frequency power: 800 W
   Flow rate of H₂ gas: 250 sccm
   Flow rate of N₂ gas: 750 sccm
   Internal pressure of processing chamber: 30 Pa
   Substrate temperature: 450° C.
   Nitrification time: 60 seconds
(b) Conditions for comparative example
   High frequency power: 800 W
   Flow rate of H₂ gas: 0 sccm
   Flow rate of N₂ gas: 1000 sccm
   Internal pressure of processing chamber: 30 Pa
   Substrate temperature: 450° C.
   Nitrification time: 60 seconds

As shown in FIG. 4, Example 1 showed signal intensity higher than that in the comparative prior art example and provided an increased rate of about 38% in the nitrogen concentration in the silicon oxide film. It can be seen that nitrification using the H₂ gas and N₂ gas shows an increase in the nitrogen concentration, i.e., nitrification speed in the silicon oxide film obtained for the fixed nitrification time (60 seconds) as compared to nitrification using the N₂ gas solely.

In addition, bond states of nitrogen in the silicon oxide film for respective samples observed according to X-ray photoelectron spectroscopy were compared. It could be seen from this comparison that the nitrogen in the silicon oxide film according to Example 1 shows a more stable bond state. It is expected from this that it is difficult for the nitrogen to escape from the silicon oxide film during annealing after the nitrification and thus it is possible to keep the nitrogen in the film at a high concentration even after the annealing.

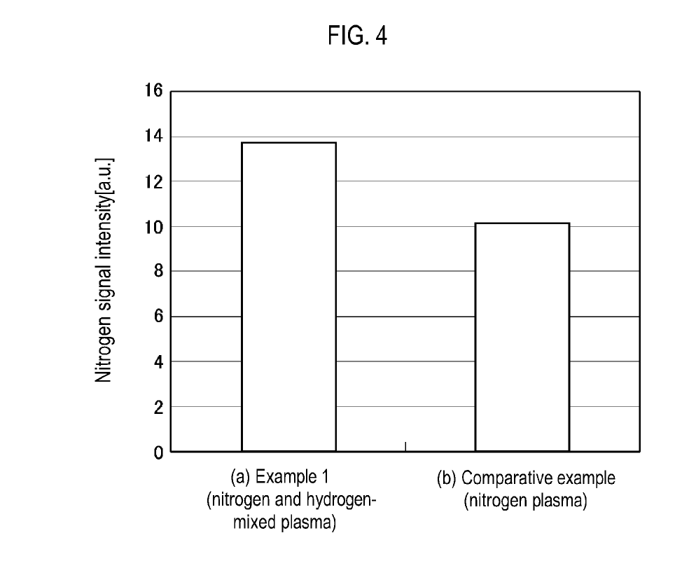

FIG. 5 is a graph showing a comparison between signal intensities of nitrogen in a thin film processed with a processing time varied between 60 and 240 seconds under the conditions (b) and signal intensity of nitrogen in a thin film prepared under the conditions (a). In FIG. 5, a vertical axis represents relative signal intensity (a. u.) of nitrogen in the silicon oxide film according to fluorescent X-ray analysis. In this figure, a symbol ♦ represents data obtained by the process performed under condition (b) and a symbol ▪ represents data obtained by the process performed under condition (a).

As shown in FIG. 5, it can be seen that, under the conditions (b), it takes about 120 seconds or more to obtain a thin film having the same nitrogen signal intensity as the thin film processed under condition (a). Thus, Example 1 can increase a nitrification speed about twice.

### Example 2

Next, Example 2 of the present disclosure will be described. In Example 2, a nitrification process was performed for respective samples under several conditions with different percentages of flow rates of N₂ gas on the basis of condition (a) and then amounts of nitrogen in the silicon oxide film for the respective samples were compared in terms of nitrogen signal intensity measured by fluorescent X-ray analysis. For comparison, nitrogen signal intensity to satisfy characteristics of a device employing a nitrified thin film was defined as a target value and a percentage of flow rate providing signal intensity exceeding the target value was reviewed.

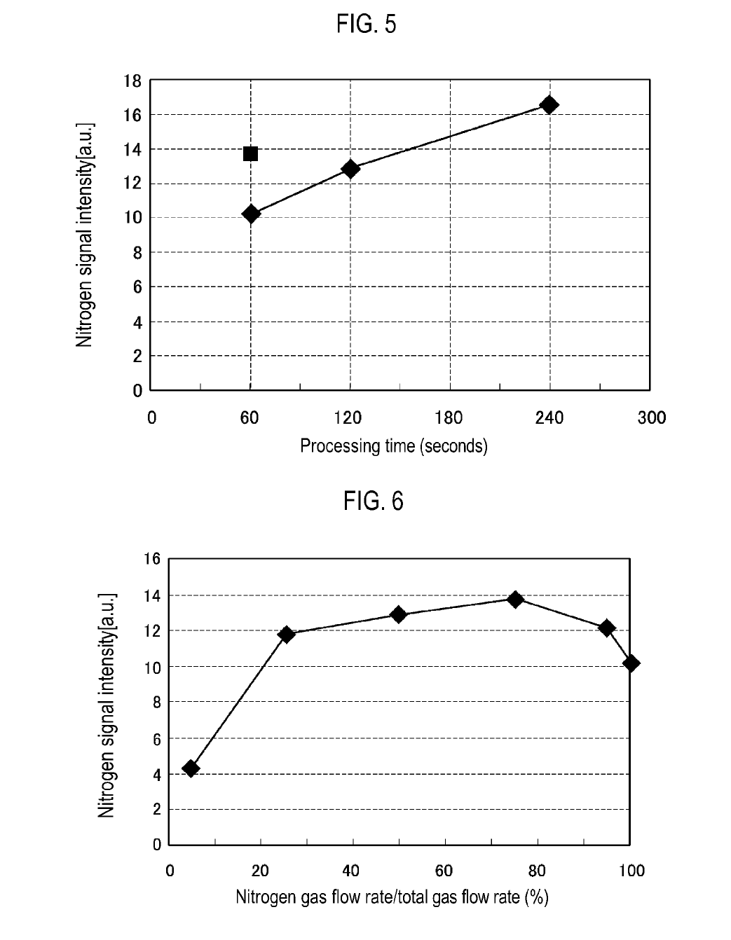

FIG. 6 shows a change in signal intensity of nitrogen in the silicon oxide film when a percentage of flow rate of N₂ gas, specifically, a percentage of flow rate of the N₂ gas with respect to the sum of flow rates of H₂ gas and N₂ gas, is changed. In FIG. 6, a horizontal axis represents a percentage of flow rate of N₂ gas and a vertical axis represents relative signal intensity (a. u.) of nitrogen in the silicon oxide film according to fluorescent X-ray analysis.

As shown in FIG. 6, a change in the percentage of flow rate of N₂ gas provided a convex graph with signal intensity increased within a particular range of percentages of flow rate. That is, a percentage of flow rate of N2 gas has an optimal value (range). A percentage of flow rate of N₂ gas providing signal intensity exceeding the target value was more than 25% and less than 95%. When this percentage is expressed in terms of a percentage of flow rate of H₂ gas (corresponding to the above-mentioned percentage R of hydrogen atoms) with respect to the sum of flow rates of H₂ gas and N₂ gas, a percentage of flow rate of H₂ gas was more than 5% and less than 75%. The signal intensity exceeds the target value within the percentage range between 5% and 75% to increase the nitrification speed of the oxide film and achieve nitrification with high concentration. In addition, it is also possible to increase the nitrification speed within a range of between 0% and 5% and a range between 75% and 80% in terms of the percentage of flow rate of H₂ gas.

### Example 3

In Example 3, the same comparison and review as Example 2 were performed under several conditions with different total flow rates of process gas.

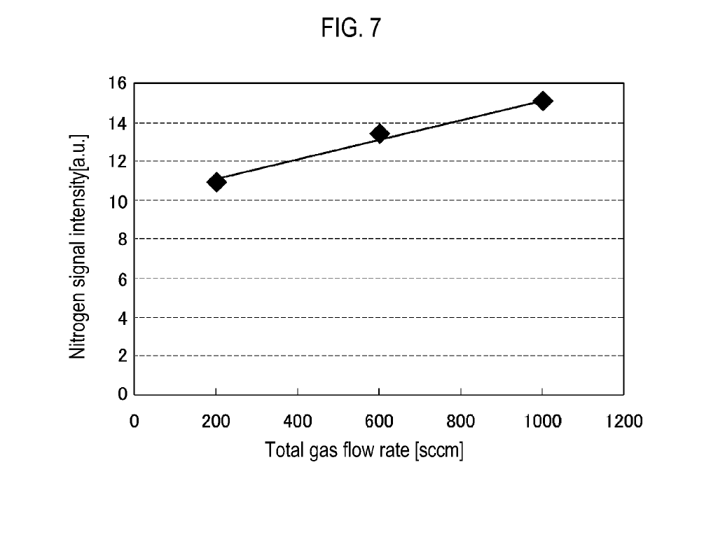

FIG. 7 shows a change in signal intensity of nitrogen in the silicon oxide film when the total flow rates of the process gas (H₂ gas and N₂ gas) are changed. In FIG. 7, a horizontal axis represents the total flow rate of H₂ gas and N₂ gas and a vertical axis represents relative signal intensity (a. u.) of nitrogen in the silicon oxide film according to fluorescent X-ray analysis.

As shown in FIG. 7, it can be seen that a higher total flow rate provides higher signal intensity, i.e., the total flow rate is approximately proportional to the signal intensity within a range of measurement. It is considered that this is attributable to increase in supplying efficiency of nitrogen activated species, which are generated when the process gas is plasmarized, onto the wafer 200. The total flow rate of H₂ gas and N₂ gas providing the signal intensity exceeding the target value was more than 600 sccm.

### Example 4

In Example 4, the same comparison and review as Example 2 were performed under several conditions with different internal pressures of the processing chamber.

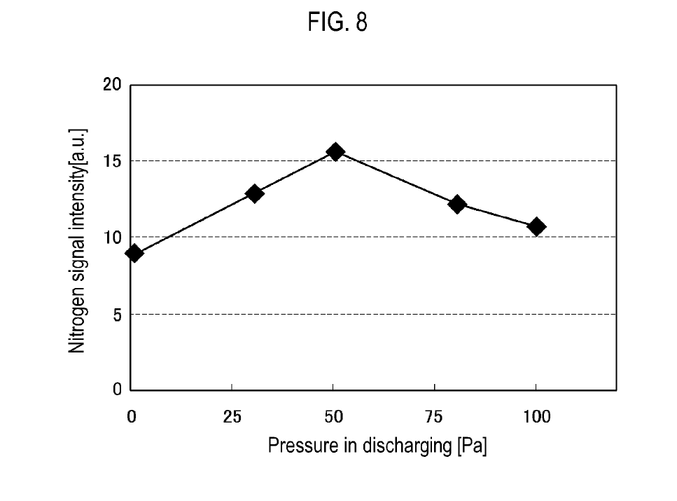

FIG. 8 shows a change in signal intensity of nitrogen in the silicon oxide film when the internal pressure of the processing chamber is changed. In FIG. 8, a horizontal axis represents the internal pressure of the processing chamber during a discharge operation and a vertical axis represents relative signal intensity (a. u.) of nitrogen in the silicon oxide film according to fluorescent X-ray analysis.

As shown in FIG. 8, a convex graph with the highest signal intensity near the processing chamber internal pressure of 50 Pa was obtained. That is, the processing chamber internal pressure has an optimal value (range). It is considered that this is because there exists a pressure range appropriate for ion formation in plasma. The processing chamber internal pressure providing increased nitrification concentration was within a range of between about 8 Pa and about 100 Pa and the processing chamber internal pressure providing the signal intensity exceeding the target value was within a range of between 25 Pa and 80 Pa.

### <Aspects of Present Disclosure>

Hereinafter, additional aspects of the present disclosure will be additionally stated.

A first aspect of the present disclosure may provide a method of manufacturing a semiconductor device, including: supporting and heating a substrate having an oxide film formed thereon using a substrate support member provided in a processing chamber; adjusting flow rates of hydrogen-containing gas and nitrogen-containing gas in a process gas using a gas flow rate controller to set a percentage R of the number of hydrogen atoms with respect to the total number of hydrogen atoms and nitrogen atoms contained in the process gas to be 0%<R≦80%; supplying the process gas with the adjusted flow rates into the processing chamber by using a gas supplying unit; exciting the process gas supplied into the processing chamber by using a plasma generator; and processing the substrate with the excited process gas.

A second aspect of the present disclosure provides a method of manufacturing a semiconductor device, including: carrying a substrate having an oxide film and a nitride film stacked thereon into a processing chamber; supporting and heating the substrate using a substrate support member provided in the processing chamber; adjusting flow rates of hydrogen-containing gas and nitrogen-containing gas in process gas using a gas flow rate controller to set a percentage R of the number of hydrogen atoms with respect to the total number of hydrogen atoms and nitrogen atoms contained in the process gas to be 0%<R≦80%; supplying the process gas with the adjusted flow rates into the processing chamber using a gas supplying unit; exciting the process gas supplied into the processing chamber by using a plasma generator; processing the substrate with the excited process gas; and carrying the substrate out of the processing chamber.

In one embodiment, the step of adjusting flow rates includes setting the percentage R to be 5%≦R≦75%.

In one embodiment, silicon is contained in the oxide film.

In one embodiment, silicon is contained in the nitride film.

In one embodiment, the oxide film is formed on one or both of the top and bottom surfaces of the nitride film.

In one embodiment, the process gas comprises at least one of hydrogen gas, nitrogen gas and ammonia gas.

In one embodiment, the total flow rate of the process gas is more than 600 sccm.

In one embodiment, the internal pressure of the processing chamber when the substrate is processed is more than 25 Pa and less than 80 Pa.

In one embodiment, the step of processing the substrate includes adjusting a bias voltage of the substrate using an impedance adjusting unit connected to an impedance tuning electrode provided in the substrate support member.

A third aspect of the present disclosure provides a substrate processing apparatus including: a processing chamber into which a substrate having an oxide film and a nitride film stacked thereon is carried; a substrate support member provided in the processing chamber to support and heat the substrate; a gas flow rate controller configured to adjust flow rates of hydrogen-containing gas and nitrogen-containing gas in a process gas; a gas supplying unit configured to supply the process gas into the processing chamber; a plasma generator configured to excite the process gas; and a control unit configured to control the substrate support member, the gas flow rate controller, the gas supplying unit and the plasma generator, wherein the control unit performs a control operation to heat the substrate carried in the processing chamber, adjust the flow rates of hydrogen-containing gas and nitrogen-containing gas such that a percentage R of the number of hydrogen atoms with respect to the total number of hydrogen atoms and nitrogen atoms in the process gas is set to be 0%<R≦80%, supply the process gas with the adjusted flow rates into the processing chamber, excite the process gas supplied into the processing chamber, and process the substrate with the excited process gas.

In one embodiment, the control unit controls the respective components to set the percentage R to be 5%≦R≦75%.

In one embodiment, the substrate processing apparatus further includes an impedance adjusting unit connected to an impedance tuning electrode provided in the substrate support member to adjust a bias voltage of the substrate, wherein the control unit controls the impedance adjusting unit to process the substrate while adjusting the bias voltage of the substrate.

According to the present disclosure, a method of manufacturing a semiconductor device and a substrate processing apparatus capable of increasing nitrification speed of an oxide film are provided.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device, the method comprising:
carrying a substrate into a processing chamber, the substrate having an oxide film and a nitride film stacked thereon;
supporting and heating the substrate using a substrate support member provided in the processing chamber;
adjusting flow rates of hydrogen-containing gas and nitrogen-containing gas in a process gas using a gas flow rate controller to set a percentage R of the number of hydrogen atoms with respect to the total number of hydrogen atoms and nitrogen atoms contained in the process gas to be 0%<R≦80%;
supplying the process gas with the adjusted flow rates into the processing chamber using a gas supplying unit;
exciting the process gas supplied into the processing chamber using a plasma generator;
processing the substrate with the excited process gas; and
carrying the substrate out of the processing chamber.

2. The method of claim 1, wherein silicon is contained in the oxide film.

3. The method of claim 1, wherein silicon is contained in the nitride film.

4. The method of claim 1, wherein the oxide film is formed on at least one of the top and bottom surfaces of the nitride film.

5. The method of claim 1, wherein the oxide film is formed on one or both of the top and bottom surfaces of the nitride film.

6. The method of claim 1, wherein the step of processing the substrate includes adjusting a bias voltage of the substrate using an impedance adjusting unit connected to an impedance tuning electrode provided in the substrate support member.

7. A substrate processing apparatus comprising:
a processing chamber configured to receive a substrate having an oxide film and a nitride film stacked thereon;
a substrate support member provided in the processing chamber, the substrate support member configured to support and heat the substrate;
a gas flow rate controller configured to adjust flow rates of hydrogen-containing gas and nitrogen-containing gas in a process gas;
a gas supplying unit configured to supply the process gas into the processing chamber,
a plasma generator configured to excite the process gas; and
a control unit configured to control the substrate support member, the gas flow rate controller, the gas supplying unit and the plasma generator,
wherein the control unit controls the substrate support member to heat the substrate carried in the processing chamber, controls the gas flow rate controller to adjust the flow rates of hydrogen-containing gas and nitrogen-containing gas such that a percentage R of the number of hydrogen atoms with respect to the total number of hydrogen atoms and nitrogen atoms in the process gas is set to be 0%<R≦80%, controls the gas supplying unit to supply the process gas with the adjusted flow rates into the processing chamber, and controls the plasma generator to excite the process gas supplied into the processing chamber and process the substrate with the excited process gas.

8. The substrate processing apparatus of claim 7, further comprising: an impedance adjusting unit connected to an impedance tuning electrode provided in the substrate support member to adjust a bias voltage of the substrate, wherein the control unit controls the impedance adjusting unit to process the substrate while adjusting the bias voltage of the substrate.
